(19) United States
(12) Patent Application Publication
(10) Pub. No.: US 2014/0363903 A1
(43) Pub. Date: Dec. 11, 2014

(54) SUBSTRATE TREATING APPARATUS AND METHOD OF TREATING SUBSTRATE

(71) Applicant: Tokyo Ohta Kogyo Co., Ltd., Kawasaki-shi (JP)

(72) Inventors: Hidenori Miyamoto, Hillsboro, OR (US); Yubun Kikuchi, Hillsboro, OR (US); Tsutomu Sahoda, Kawasaki-shi (JP); Yoshiaki Masu, Kawasaki-shi (JP)

(73) Assignee: Tokyo Ohta Kogyo Co., Ltd., Kawasaki-shi (JP)

(21) Appl. No.: 13/914,098

(22) Filed: Jun. 10, 2013

(51) Int. Cl. H01L 21/66; H01L 21/02; H01L 21/324; H01L 21/67

(52) U.S. Cl. CPC H01L 22/26; H01L 21/67253; H01L 21/02664; H01L 21/324
USPC 438/5; 118/712; 118/708

(57) ABSTRACT

A substrate treating apparatus including: a chamber capable of accommodating a substrate; a treating part which conducts a predetermined treatment associated with forming a coating film containing a metal to the substrate accommodated in the chamber; and a detection part which detects a concentration of a predetermined gas containing a chalcogen element within a gas inside the chamber.

### FIELD OF THE INVENTION

The present invention relates to a substrate treating apparatus and a substrate treating method.

### DESCRIPTION OF THE RELATED ART

A CIGS solar cell or a CZTS solar cell formed by semiconductor materials including a metal such as Cu, Ge, Sn, Pb, Sb, Bi, Ga, In, Zn, and a combination thereof, and a chalcogen element such as S, Se, Te, and a combination thereof has been attracting attention as a solar cell having high conversion efficiency (for example, see Patent Documents 1 to 3).

For example, a CZTS solar cell has a structure in which a film including four types of semiconductor materials, namely, Cu, Zn, Sn, and Se is used as a light absorbing layer (photoelectric conversion layer). In such solar cells, a configuration is known in which a back electrode made of molybdenum is provided on a substrate such a glass, and the aforementioned light absorbing layer is provided on the back electrode.

In a CZTS solar cell, since it is possible to reduce the thickness of the light absorbing layer compared to a conventional solar cell, it is easy to install the CIGS solar cell on a curved surface and to transport the CIGS solar cell. For this reason, it is expected that CIGS solar cells can be used in various application fields as a high-performance, flexible solar cell. As a method of forming the light absorbing layer, a method of forming the light absorbing layer through depositing or sputtering is conventionally known (for example, see Patent Documents 2 to 5).

### Documents of Related Art

### Patent Documents

[Patent Document 1] Japanese Unexamined Patent Application, First Publication No. Hei 11-340482

[Patent Document 2] Japanese Unexamined Patent Application, First Publication No. 2005-51224

[Patent Document 3] Published Japanese Translation No. 2009-537997 of the PCT International Publication

[Patent Document 4] Japanese Unexamined Patent Application, First Publication No. Hei 1-231313

[Patent Document 5] Japanese Unexamined Patent Application, First Publication No. Hei 11-273783

### SUMMARY OF THE INVENTION

In contrast, as the method of forming the light absorbing layer, the present inventors propose a method of coating the semiconductor materials in the form of a liquid material on a substrate, followed by heating the substrate to form a coating film. In such a method of forming the light absorbing layer, the following problems arise.

Depending on the heating conditions such as the temperature and the pressure in the heating of the substrate, the film quality of the formed coating film changes. For forming a coating film having a high film quality, it is required to control the ambient environment of the substrate at the time of heating, and in order to do so, it is required to detect the change in the ambient environment of the substrate. In this regard, it is not limited to heat treatment. For example, in other substrate treatments such as the coating treatment in which a liquid material is applied to the substrate, like in the heat treatment, it is required to detect the change in the ambient environment of the substrate.

The present invention takes the above circumstances into consideration, with an object of providing a substrate treating apparatus and a substrate treating method capable of detecting the change in the ambient environment of the substrate at the time of treating the substrate.

A first aspect of the present invention is a substrate treating apparatus including: a chamber capable of accommodating a substrate; a treating part which conducts a predetermined treatment associated with forming a coating film containing a metal to the substrate accommodated in the chamber; and a detection part which detects a concentration of a predetermined gas containing a chalcogen element within a gas inside the chamber.

According to the above configuration, by virtue of including a detection part which detects a concentration of a predetermined gas containing a chalcogen element within a gas inside the chamber, it becomes possible to detect the change in the concentration of the predetermined gas containing a chalcogen element in the ambience of the substrate. As a result, it becomes possible to detect the change in the ambient environment of the substrate at the time of conducting a predetermined treatment associated with forming a coating film containing a metal to the substrate.

In the substrate treating apparatus, the predetermined treatment preferably includes at least one treatment selected from the group consisting of a coating treatment in which a liquid material containing the metal and a solvent is applied to the substrate, and a heating treatment in which the substrate having the liquid material coated thereon is heated.

According to the above configuration, it becomes possible to detect the change in the concentration of the predetermined gas containing a chalcogen element in the ambience of the substrate during the coating treatment and the heating treatment.

The substrate treating apparatus preferably further includes a control part which controls the concentration of the predetermined gas inside the chamber, using a detection result of the detection part.

According to the above configuration, by virtue of the control part, since the concentration of the predetermined gas inside the chamber can be controlled using a detection result of the detection part, it becomes possible to obtain a substrate treating apparatus which has an excellent ability of controlling the ambient environment of the substrate.

In the substrate treating apparatus, the control part preferably includes a supply part which supplies at least one of the predetermined gas and a solid containing the chalcogen element into the chamber.

According to the above configuration, by virtue of the control part including a supply part which supplies at least one of the predetermined gas and a solid containing the chalcogen element into the chamber, the concentration of the predetermined gas containing the chalcogen element can be increased when the detection result shows that the concentration of the predetermined gas is lower than a predetermined value.

In the substrate treating apparatus, the control part preferably includes an exhaust part which discharges the predetermined gas inside the chamber.

According to the above configuration, by virtue of the control part including an exhaust part which discharges the predetermined gas inside the chamber, the concentration of the predetermined gas containing the chalcogen element can be decreased when the detection result shows that the concentration of the predetermined gas is higher than a predetermined value.

In the substrate treating apparatus, the detection part is preferably disposed near the exhaust part.

According to the above configuration, since the detection part is disposed near the exhaust part, the concentration of the predetermined gas within a gas discharged from the exhaust part can be detected.

In the substrate treating apparatus, the detection part is preferably disposed to oppose a face of the substrate on which the liquid material is coated.

According to the above configuration, since the detection part is disposed to oppose a face of the substrate on which the liquid material is coated, it becomes possible to efficiently measure the ambience of the face of the substrate on which the liquid material is coated.

In the substrate treating apparatus, the detection part is preferably provided at a plurality of portions inside the chamber.

According to the above configuration, since the detection part is provided at a plurality of portions inside the chamber, the ambient environment of the substrate can be detected by the detection part at a plurality of portions. As a result, an accurate detection result on the ambient environment of the substrate can be obtained.

In the substrate treating apparatus, the predetermined gas preferably includes at least one of hydrogen sulfide and hydrogen selenide.

According to the above configuration, it becomes possible to know the concentration of a predetermined gas containing at least one of hydrogen sulfide and hydrogen selenide as the ambient environment of the substrate at the time of heating.

A second aspect of the present invention is a substrate treating apparatus including: a first chamber capable of accommodating a substrate; a first treating part which conducts a first treatment associated with forming a coating film containing a metal to the substrate accommodated in the first chamber; a second chamber capable of accommodating the substrate to which the first treatment has been conducted; a second treating part which conducts a second treatment associated with forming a coating film containing a metal to the substrate accommodated in the second chamber; and a detection part which detects a concentration of a predetermined gas containing a chalcogen element within a gas inside at least one of the first chamber and the second chamber.

According to the above configuration, in the case where a first treatment of the substrate is conducted in the first chamber, and a second treatment is conducted in the second chamber after conducting the first treatment, it becomes possible to detect a concentration of a predetermined gas containing a chalcogen element within a gas inside at least one of the first chamber and the second chamber. As a result, the change in the ambient environment of the substrate can be detected during at least one of the first treatment and the second treatment.

In the substrate treating apparatus, it is preferable that the first treatment includes a coating treatment in which a liquid material containing the metal and a solvent is applied to the substrate, and the second treatment includes a heating treatment in which the substrate having the liquid material coated thereon is heated.

According to the above configuration, in the case where the substrate is subjected to a coating treatment, followed by a heating treatment, the change in the ambient environment of the substrate can be detected during at least one of the coating treatment and the heating treatment.

A third aspect of the present invention is a substrate treating method including: an accommodation step in which a substrate is accommodated in a chamber; a treating step in which a predetermined treatment associated with forming a coating film containing a metal is conducted to the substrate accommodated in the chamber; and a detection step in which a concentration of a predetermined gas containing a chalcogen element within a gas inside the chamber is detected during the treating step.

According to the above configuration, by virtue of including a detection step in which a concentration of a predetermined gas containing a chalcogen element within a gas inside the chamber is detected, it becomes possible to detect the change in the concentration of the predetermined gas containing a chalcogen element in the ambience of the substrate. As a result, it becomes possible to detect the change in the ambient environment of the substrate at the time of conducting the treating step in which a treatment associated with forming a coating film containing a metal is conducted to the substrate.

In the substrate treating method, the predetermined treatment preferably includes at least one treatment selected from the group consisting of a coating treatment in which a liquid material containing the metal and a solvent is applied to the substrate, and a heating treatment in which the substrate having the liquid material coated thereon is heated.

According to the above configuration, it becomes possible to detect the change in the concentration of the predetermined gas containing a chalcogen element in the ambience of the substrate during the coating treatment and the heating treatment.

The substrate treating method preferably further includes a controlling step in which the concentration of the predetermined gas inside the chamber is controlled using a detection result of the detection step.

According to the above configuration, since the concentration of the predetermined gas inside the chamber is controlled using the detection result, the ambient environment can be controlled to a desired state. As such, a substrate treating method which exhibits an excellent ability of controlling the ambient environment of the substrate can be provided.

In the substrate treating method, the controlling step preferably includes a supplying step in which at least one of the predetermined gas and a solid containing the chalcogen element is supplied into the chamber.

According to the above configuration, by virtue of supplying at least one of the predetermined gas and a solid containing the chalcogen element into the chamber, the concentration of the predetermined gas containing the chalcogen element can be increased when the detection result shows that the concentration of the predetermined gas is lower than a predetermined value.

In the substrate treating method, the controlling step preferably includes a discharge step in which the predetermined gas inside the chamber is discharged from an exhaust part.

According to the above configuration, by virtue of discharging the predetermined gas inside the chamber, the concentration of the predetermined gas containing the chalcogen element can be decreased when the detection result shows that the concentration of the predetermined gas is higher than a predetermined value.

In the substrate treating method, the detection step preferably includes detecting the concentration of the predetermined gas near the exhaust part.

According to the above configuration, the concentration of the predetermined gas within a gas discharged from the exhaust part can be detected.

In the substrate treating method, the detection step preferably includes detecting the concentration of the predetermined gas at a position opposite to a face of the substrate on which the liquid material is coated.

According to the above configuration, since the concentration of the predetermined gas is detected at a position opposite to a face of the substrate on which the liquid material is coated, it becomes possible to efficiently measure the ambience of the face of the substrate on which the liquid material is coated.

In the substrate treating method, the detection step preferably includes detecting the concentration of the predetermined gas at a plurality of portions inside the chamber.

According to the above configuration, since the concentration of the predetermined gas is detected at a plurality of portions inside the chamber, the ambient environment of the substrate can be detected at a plurality of portions. As a result, an accurate detection result on the ambient environment of the substrate can be obtained.

In the substrate treating method, the predetermined gas preferably includes at least one of hydrogen sulfide and hydrogen selenide.

According to the above configuration, it becomes possible to know the concentration of a predetermined gas containing at least one of hydrogen sulfide and hydrogen selenide as the ambient environment of the substrate at the time of heating.

A fourth aspect of the present invention is a substrate treating method including: a first accommodation step in which a substrate is accommodated in a first chamber; a first treating step in which a first treatment associated with forming a coating film containing a metal is conducted to the substrate accommodated in the first chamber; a second accommodation step in which the substrate to which the first treatment has been conducted is accommodated in a second chamber; a second treating step in which a second treatment associated with forming a coating film containing a metal is conducted to the substrate accommodated in the second chamber; and a detection step in which a concentration of a predetermined gas containing a chalcogen element within a gas inside a chamber where the substrate has been accommodated in at least one of the first treating step and the second treating step is detected.

According to the above configuration, it becomes possible to detect a concentration of a predetermined gas containing a chalcogen element within a gas inside a chamber in which the substrate is accommodated in the first step and the second step. As a result, the change in the ambient environment of the substrate can be detected during at least one of the first treatment and the second treatment.

In the substrate treating methods, it is preferable that the first treatment includes a coating treatment in which a liquid material containing the metal and a solvent is applied to the substrate, and the second treatment includes a heating treatment in which the substrate having the liquid material coated thereon is heated.

According to the above configuration, it becomes possible to detect the change in the concentration of the predetermined gas containing a chalcogen element in the ambience of the substrate during the coating treatment and the heating treatment.

According to the present invention, there are provided a substrate treating apparatus and a substrate treating method capable of detecting the change in the ambient environment of the substrate at the time of treating the substrate.

### BRIEF DESCRIPTION OF THE DRAWINGS

FIG. 1 is a diagram showing an entire configuration of a coating apparatus according to one embodiment of the present invention.

FIG. 2 is a diagram showing an entire configuration of the coating apparatus according to the present embodiment.

FIG. 3 is a diagram showing a configuration of a nozzle according to the present embodiment.

FIG. 4 is a diagram showing a configuration of part of a coating part according to the present embodiment.

FIG. 5 is a diagram showing a configuration of a vacuum drying part according to the present embodiment.

FIG. 6 is a diagram showing a configuration of part of a baking part according to the present embodiment.

FIG. 7 is a diagram showing a configuration of part of a baking part according to the present embodiment.

FIG. 8 is a diagram showing a step in a coating treatment performed by a coating apparatus according to the present embodiment.

FIG. 9 is a diagram showing a step in a coating treatment performed by a coating apparatus according to the present embodiment.

FIG. 10 is a diagram showing a step in a coating treatment performed by a coating apparatus according to the present embodiment.

FIG. 11 is a diagram showing a step in a coating treatment performed by a coating apparatus according to the present embodiment.

FIG. 12 is a diagram showing a step in a coating treatment performed by a coating apparatus according to the present embodiment.

FIG. 13 is a diagram showing a step in a vacuum drying treatment performed by a coating apparatus according to the present embodiment.

FIG. 14 is a diagram showing a step in a vacuum drying treatment performed by a coating apparatus according to the present embodiment.

FIG. 15 is a diagram showing a step in a vacuum drying treatment performed by a coating apparatus according to the present embodiment.

FIG. 16 is a diagram showing a step in a vacuum drying treatment performed by a coating apparatus according to the present embodiment.

FIG. 17 is a diagram showing a step in a baking treatment performed by a coating apparatus according to the present embodiment.

FIG. 18 is a diagram showing a step in a baking treatment performed by a coating apparatus according to the present embodiment.

FIG. 19 is a diagram showing a step in a baking treatment performed by a coating apparatus according to the present embodiment.

FIG. 20 is a diagram showing a step in a baking treatment performed by a coating apparatus according to the present embodiment.

FIG. 21 is a diagram showing a step in a baking treatment performed by a coating apparatus according to the present embodiment.

FIG. 22 is a diagram showing a step in a baking treatment performed by a coating apparatus according to a modified example.

FIG. 23 is a diagram showing a configuration of a coating apparatus according to a modified example.

FIG. 24 is a diagram showing a configuration of a coating apparatus according to a modified example.

### DETAILED DESCRIPTION OF THE INVENTION

Hereinafter, one embodiment of the present invention will be described with reference to the accompanying drawings.

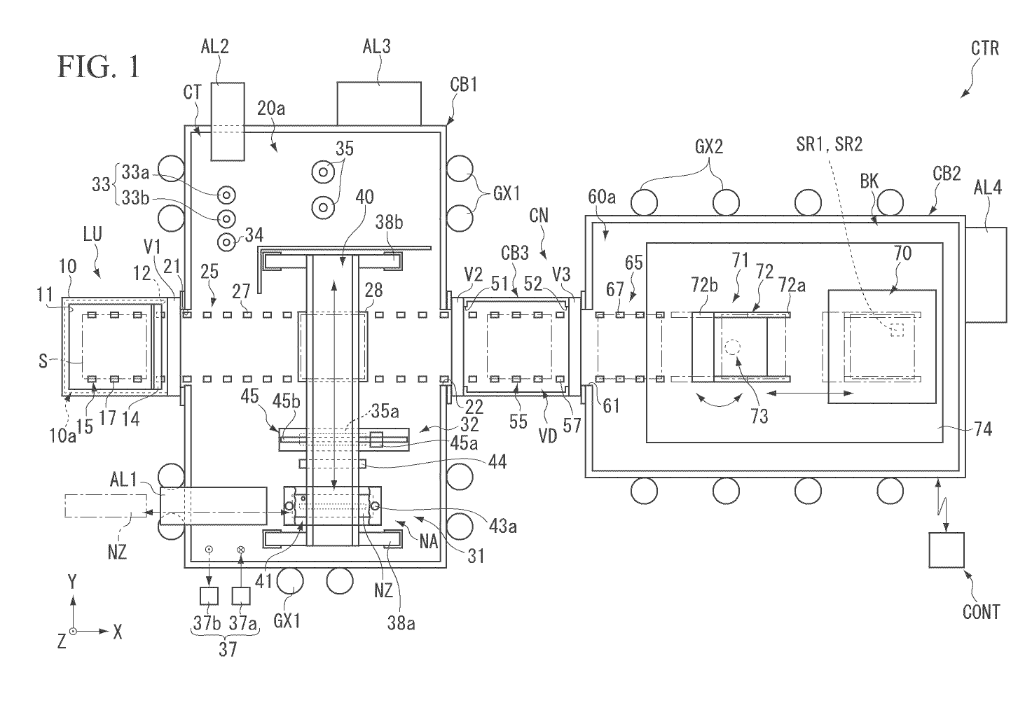

FIG. 1 is a schematic diagram showing a configuration of a coating apparatus (substrate treating apparatus) CTR according to one embodiment of the present invention.

As shown in FIG. 1, the coating apparatus CTR is an apparatus which applies a liquid material to a substrate S. The coating apparatus CTR includes a substrate loading/unloading part LU, a first chamber CB1, a second chamber CB2, a connection part CN and a control part CONT. The first chamber CB1 has a coating part CT. The second chamber CB2 has a baking part BK. The connection part CN has a vacuum drying part VD.

The coating apparatus CTR is used, for example, by being disposed on a floor FL in a factory. The coating apparatus may have a configuration in which the coating apparatus is accommodated in one room, or a configuration in which the coating apparatus is divisionally accommodated in a plurality of rooms. In the coating apparatus CTR, the substrate loading/unloading part LU, the coating part CT, the vacuum drying part VD and the baking part BK are arranged in this order in one direction.

With respect to the configuration of the coating apparatus CTR, it is not particularly limited that the substrate loading/unloading part LU, the coating part CT, the vacuum drying part VD and the baking part BK are arranged in this order in one direction. For example, the substrate loading/unloading part LU may be divided into a substrate loading part (not shown) and a substrate unloading part (not shown). Further, the vacuum drying part VD may be omitted. Needless to say, the aforementioned parts may not be arranged in one direction, and a configuration may be employed in which the aforementioned parts are arranged to be stacked in a vertical or horizontal direction with a robot (not shown) disposed at a central position.

In the respective drawings as below, upon describing the configuration of a coating apparatus, for the purpose of simple marking, an XYZ coordinate system is used to describe the directions in the drawings. In the XYZ coordinate system, the plane parallel to the floor is regarded as the XY plane. On the XY plane, the direction in which the components of the coating apparatus CTR (the substrate loading/unloading part LU, the coating part CT, the vacuum drying part VD and the baking part BK) are arranged is marked as the X direction, and the direction perpendicular to the X direction on the XY plane is marked as the Y direction. The direction perpendicular to the XY plane is marked as the Z direction. In the X, Y, and Z directions, the arrow direction in the drawing is the +direction, and the opposite direction of the arrow direction is the −direction.

In this embodiment, as the substrate S, for example, a plate-shaped member made of glass, resin, or the like may be used. Further, in this embodiment, molybdenum is sputtered on the substrate S as a back electrode. Needless to say, any other electroconductive material may be used as a back electrode. Explanation will be given below, taking an example of a substrate having a size of 330 mm×330 mm as viewed in the Z direction. The size of the substrate is not limited to 330 mm×330 mm. For example, as the substrate S, a substrate having a size of 125 mm×125 mm may be used, or a substrate having a size of 1 m×1 m may be used. Needless to say, a substrate having a size larger than the aforementioned sizes or a substrate having a size smaller than the aforementioned sizes may be appropriately used.

In this embodiment, as the liquid material to be applied to the substrate S, for example, a liquid composition is used which includes a predetermined solvent and a metal such as a combination of copper (Cu), indium (In), gallium (Ga), and selenium (Se) or a combination of copper (Cu), zinc (Zn), tin (Sn) and selenium (Se). The liquid composition includes a metal material for forming a light absorbing layer (photoelectric conversion layer) of a CIGS solar cell or a CZTS solar cell.

In the present embodiment, the liquid composition contains a substance for obtaining the grain size of a light absorbing layer of a CIGS solar cell or a CZTS solar cell. Needless to say, as the liquid material, a liquid material in which another metal (such as metal nano particles) is dispersed in the solution may be used.

(Substrate Loading/Unloading Part)

The substrate loading/unloading part LU loads a substrate S prior to being treated on the coating part CT, and unloads the treated substrate S from the coating part CT. The substrate loading/unloading part LU has a chamber 10. The chamber 10 is formed in the shape of a rectangular box. Inside the chamber 10, an accommodation room 10a capable of accommodating the substrate S is formed. The chamber 10 has a first opening 11, a second opening 12 and a lid portion 14. The first opening 11 and the second opening 12 communicates the accommodation room 10a with the outside of the chamber 10.

The first opening 11 is formed on a +Z-side face of the chamber 10. The first opening 11 is formed to have a size larger than the size of the substrate S as viewed in the Z direction. The substrate S to be taken out of the chamber 10 or the substrate S to be accommodated in the accommodation room 10a is place into or taken out of the substrate loading/unloading part LU through the first opening 11.

The second opening 12 is formed on a +X-side face of the chamber 10. The second opening 12 is formed to have a size larger than the size of the substrate S as viewed in the X direction. The substrate S supplied to the coating part CT or the substrate S returned from the coating part CT is place into or taken out of the substrate loading/unloading part LU through the second opening 12.

The lid portion 14 opens or closes the first opening 11. The lid portion 14 is formed in the shape of a rectangular plate. The lid portion 14 is attached to a +X-side edge of the first opening 11 via a hinge portion (not shown). Thus, the lid portion 14 is rotatable around the Y-axis, with the +X-side edge of the first opening 11 as the center. By rotating the lid portion 14 around the Y-axis, the first opening 11 can be opened or closed.

The accommodation room 10a is provided with a substrate transporting part 15. The substrate transporting part 15 includes a plurality of rollers 17. The rollers 17 are arranged in a pair in the Y-direction, and a plurality of the pairs are arranged in the X-direction.

Each of the rollers 17 is adapted to be rotatable about the Y direction serving as the central axis. The plurality of rollers 17 are formed to have the same diameter, and the +Z-side end of the plurality of rollers 17 are arranged on a same plane parallel to the XY plane. Thus, the plurality of rollers 17 are capable of supporting the substrate S in a state where the substrate S is parallel to the XY plane.

The rotation of each of the rollers 17 is controlled, for example, by a roller-rotation control part (not shown). By rotating each of the rollers 17 clockwise or anti-clockwise around the Y-axis in a state where the substrate S is supported by the plurality of rollers 17, the substrate transporting part 15 can transport the substrate S in an X-direction (+X-direction or −X-direction). As the substrate transporting part 15, a float transporting part (not shown) may be used to lift the substrate for transportation.

(First Chamber)

The first chamber CB1 is mounted on the base BC placed on the floor FL. The first chamber CB1 is formed in the shape of a rectangular box. Inside the first chamber CB1, an accommodation room 20a is formed. The coating part CT is provided in the treatment room 20a. The coating part CT performs the coating treatment of the liquid material on the substrate S.

The first chamber CB1 has a first opening 21 and a second opening 22. The first opening 21 and the second opening 22 communicate the treatment 20a with the outside of the first chamber CB1. The first opening 21 is formed on a −X-side face of the first chamber CB1. The second opening 22 is formed on a +X-side face of the first chamber CB1. The first opening 21 and the second opening 22 are formed to have a size which allows the substrate S to pass through. The substrate S is placed in or taken out of the first chamber CB1 through the first opening 21 and the second opening 22.

The coating part CT has an ejection part 31, a maintenance part 32, a liquid material supply part 33, a washing liquid supply part 34, a waste liquid storing part 35, a gas supply/exhaust part 37 and a substrate transporting part 25.

The ejection part 31 has a nozzle NZ, a treatment stage 28 and a nozzle actuator NA.

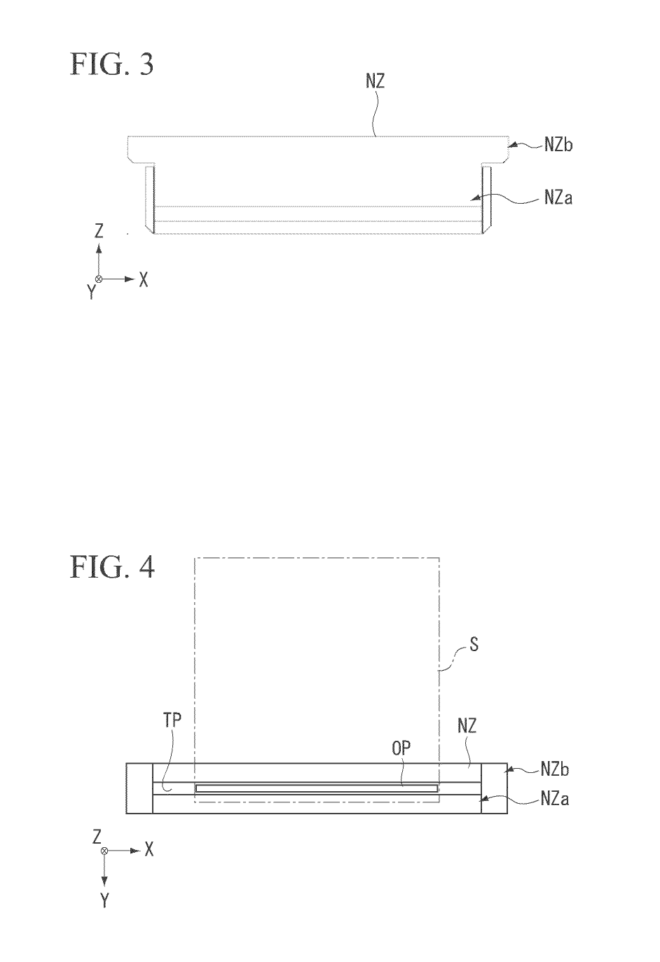

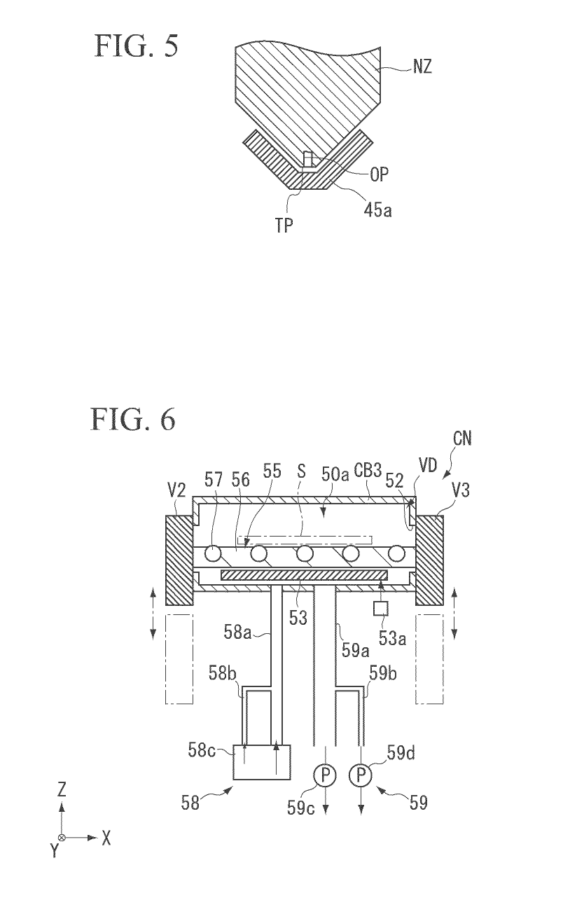

FIG. 3(a) is a diagram showing a configuration of the slit nozzle NZ.

As shown in FIG. 3(a), the nozzle NZ is formed to have an elongate shape, and is arranged such that the lengthwise direction thereof is in parallel to the X direction. The nozzle NZ has a main part NZa and a protruding part NZb. The main part NZa is a housing capable of accommodating the liquid material inside thereof. The main part NZa is made of, for example, a material containing titanium or a titanium alloy. The protruding part NZb is formed to protrude from the main part NZa on the +X-side and the −X-side. The protruding part NZb is held by part of the nozzle actuator NA.

FIG. 3(b) shows the configuration when the nozzle NZ is viewed from the −Z direction side thereof.

As shown in FIG. 3(b), the nozzle NZ has an ejection opening OP on the −Z-side end (tip TP) of the main part NZa. The ejection opening OP is an opening for ejecting a liquid material. The ejection opening OP is formed as a slit elonging in the X direction. The ejection opening OP is formed, for example, so that the longitudinal direction thereof is substantially equal to the X-direction dimension of the substrate S.

The nozzle NZ ejects, for example, a liquid material in which four types of metals, namely, Cu, In, Ga, and Se are mixed with a predetermined composition ratio. The nozzle NZ is connected to a liquid supply part 33 via a connection pipe or the like (not shown). The nozzle NZ includes a holding part which holds the liquid material therein. A temperature control part which controls the temperature of the liquid material held by the holding part may be provided.

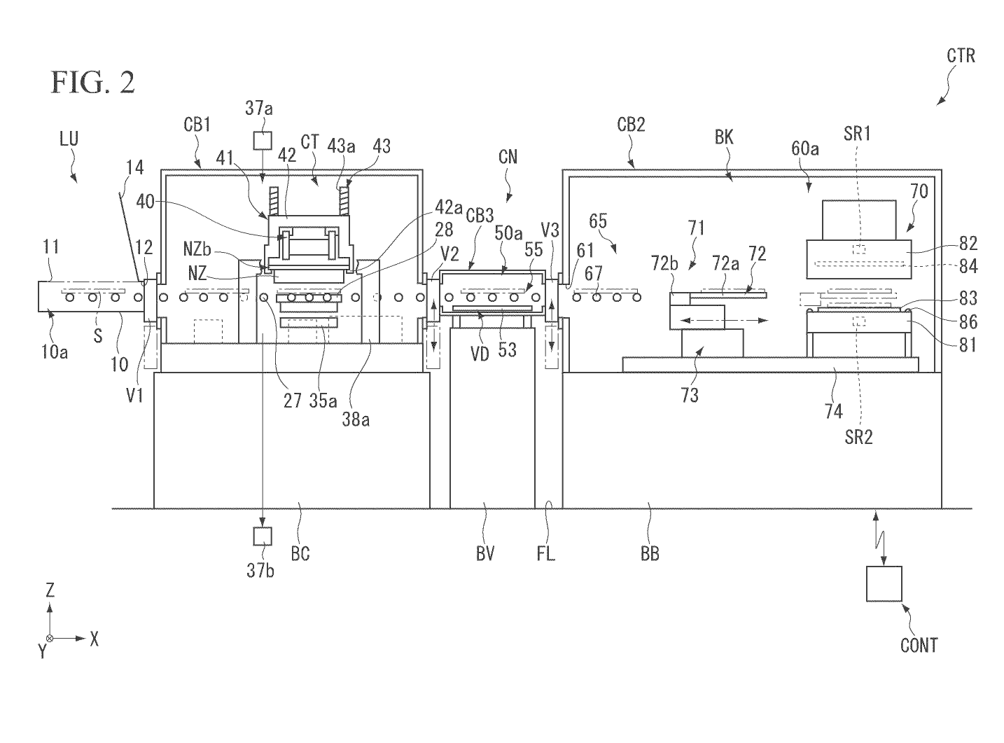

Returning to FIG. 1 and FIG. 2, the substrate S to be subjected to a coating treatment is mounted on the treatment stage 28. The +Z-side face of the treatment stage 28 is a substrate mounting face where the substrate S is mounted. The substrate mounting face is formed to be in parallel with the XY plane. The treatment stage 28 is made of, for example, stainless steel.

The nozzle actuator NA moves the nozzle NZ in the X direction. The nozzle actuator NA has a stator 40 and a mover 41 which constitutes a linear motor mechanism. As the nozzle actuator NA, any other actuator having another configuration such as a ball screw configuration may be used. The stator 40 is elongated in the Y direction. The stator 40 is supported by a support frame 38. The support frame 38 has a first frame 38a and a second frame 38b. The first frame 38a is provided on a −Y-side end portion of the treatment room 20a. The second frame 38b is provided in the treatment room 20a such that the treatment stage 28 is positioned between the first frame 38a and the second frame 38b.

The mover 41 is movable along the direction where the stator 40 is elonged (Y direction). The mover 41 has a nozzle supporting member 42 and an elevator part 43. The nozzle supporting member 42 is formed in the shape of a gate, and has a holding part 42a which holds the protruding part NZb of the nozzle NZ. The nozzle supporting member 42 integrally moves with the elevator part 43 along the stator 40 between the first frame 38a and the second 38b in the Y direction. Thus, the nozzle NZ held by the nozzle supporting member 42 moves in the Y direction over the treatment stage 28. The nozzle supporting member 42 moves along the elevation guide 43a of the elevator part 43 in the Z direction. The mover 41 has an actuator source (not shown) which moves the nozzle supporting member 42 in the Y direction and the Z direction.

The maintenance part 32 is where the maintenance of the nozzle NZ is performed. The maintenance part 32 has a nozzle standby part 44 and a nozzle-tip control part 45.

The nozzle standby part 44 has a dipping part (not shown) where the tip TP of the nozzle NZ is dipped to prevent it from drying, and a discharge part (not shown) which discharges the liquid material held within the nozzle NZ when the nozzle NZ is changed or the liquid material to be supplied to the nozzle NZ is changed.

The nozzle-tip control part 45 adjusts the conditions of the nozzle tip by washing the tip TP of the nozzle NZ and the vicinity thereof, and conducting preliminary ejection from the ejection opening OP of the nozzle NZ. The nozzle-tip control part 45 has a wiping part 45a which wipes the tip TP of the nozzle NZ and a guide rail 45b which guides the wiping part 45a. The nozzle-tip control part 45 is provided with a waste liquid accommodation part 35a which accommodates the liquid material discharged from the nozzle NZ and the washing liquid used for washing the nozzle NZ.

FIG. 4 is a diagram showing the cross-sectional shape of the nozzle NZ and the nozzle-tip control part 45. As shown in FIG. 4, the wiping part 45a is formed to cover the tip TP of the nozzle NZ and part of the inclined plane on the tip TP-side in the cross-sectional view.

The guide rail 45b extends in the X direction to cover the opening OP of the nozzle NZ. The wiping part 45a is adapted to be movable by an actuator source (not shown) along the guide rail 45b in the X direction. By moving the wiping part 45a in the X direction while being in contact with the tip TP of the nozzle NZ, the tip TP can be wiped.

The liquid material supply part 33 has a first liquid material accommodation part 33a and a second liquid material accommodation part 33b. The first liquid material accommodation part 33a and the second liquid material accommodation part 33b accommodate the liquid material to be applied to the substrate S. Further, the first liquid material accommodation part 33a and the second liquid material accommodation part 33b are capable of accommodating a plurality of different types of liquid materials.

The washing liquid supply part 34 accommodates a washing liquid which washes various parts of the coating part, such as the inside of the nozzle NZ and the nozzle-tip control part 45. The washing liquid supply part 34 is connected to the inside of the nozzle NZ and the nozzle-tip control part 45 via a pipe and a pump (which are not shown).

The waste liquid storing part 35 collects the liquid ejected from the nozzle NZ and is not reused. The nozzle-tip control part 45 may have a configuration in which the part which conducts the preliminary ejection and the part which washes the tip TP of the nozzle NZ are individually provided. Alternatively, the preliminary ejection may be conducted at the nozzle standby part 44.

The gas supply/exhaust part 37 has a gas supply part 37a and a gas exhaust part 37b. The gas supply part 37a supplies an inert gas such as a nitrogen gas or an argon gas to the treatment room 20a. The gas exhaust part 37b suctions the treatment room 20a, and discharges the gas in the treatment room 20a outside the first chamber CB1.

The substrate transporting part 25 transports the substrate S inside the treatment room 20a. The substrate transporting part 25 includes a plurality of rollers 27. The rollers 27 are arranged in the X-direction to be intersected into two lines by a central portion of the treatment room 20a in the Y-direction. The rollers 27 arranged in each line support the +Y-side end and −Y-side end of the substrate S.

By rotating each of the rollers 27 clockwise or anti-clockwise around the Y-axis in a state where the substrate S is supported by the plurality of rollers 27, the substrate S supported by each of the rollers 27 is transported in an X-direction (+X-direction or −X-direction). A float transporting part (not shown) may be used to lift the substrate for transportation.

(Connection Part)

The connection part CN connects the first chamber CB1 and the second chamber CB2. The substrate S is moved between the first chamber CB1 and the second chamber CB2 via the connection part CN. The connection part CN has a third chamber CB3. The third chamber CB3 is formed in the shape of a rectangular box. Inside the third chamber CB3, a treatment room 50a is formed. In the present embodiment, the treatment room 50a is provided with a vacuum drying part VD. The vacuum drying part VD dries the liquid material coated on the substrate S. The third chamber CB3 is provided with gate valves V2 and V3.

The third chamber CB3 has a first opening 51 and a second opening 52. The first opening 51 and the second opening 52 communicate the treatment room 50a with the outside of the third chamber CB3. The first opening 51 is formed on a −X-side face of the third chamber CB3. The second opening 52 is formed on a +X-side face of the third chamber CB3. The first opening 51 and the second opening 52 are formed to have a size which allows the substrate S to pass through. The substrate S is placed in or taken out of the third chamber CB3 through the first opening 51 and the second opening 52.

The vacuum drying part VD has a substrate transporting part 55, a gas supply part 58, a gas exhaust part 59 and a heating part 53.

The substrate transporting part 55 includes a plurality of rollers 57. The rollers 57 are arranged in a pair in the Y-direction, and a plurality of the pairs are arranged in the X-direction. The plurality of rollers 57 supports the substrate S which is disposed in the treatment room 50a via the first opening 51.

By rotating each of the rollers 57 clockwise or anti-clockwise around the Y-axis in a state where the substrate S is supported by the plurality of rollers 57, the substrate S supported by each of the rollers 57 is transported in an X-direction (+X-direction or −X-direction). A float transporting part (not shown) may be used to lift the substrate for transportation.

FIG. 6 is a schematic diagram showing a configuration of the vacuum drying part VD.

As shown in FIG. 6, the gas supply part 58 supplies an inert gas such as a nitrogen gas or an argon gas to the treatment room 50a. The gas supply part 58 has a first supply part 58a and a second supply part 58b. The first supply part 58a and the second supply part 58b are connected to a gas supply source 58c such as a gas bomb or a gas pipe. Supplying of a gas to the treatment room 50a is performed mainly by using the first supply part 58a. The second supply part 58b makes a fine control of the amount of gas supplied by the first supply part 58a.

The gas exhaust part 59 suctions the treatment room 50a, and discharges the gas in the treatment room 50a outside the third chamber CB3, thereby reducing the pressure inside the treatment room 50a. By reducing the pressure inside the treatment room 50a, evaporation of the solvent contained in the liquid material on the substrate S can be promoted, thereby drying the liquid material. The gas exhaust part 59 has a first suction part 59a and a second suction part 59b. The first suction part 59a and the second suction part 59b are connected to a suction source 59c and 59d such as a pump. Suction from the treatment room 50a is performed mainly by using the first suction part 59a. The second suction part 59b makes a fine control of the amount of suction by the first suction part 59a.

The heating part 53 heats the liquid material on the substrate S disposed in the treatment room 50a. As the heating part 53, an infrared device or a hot plate is used. The temperature of the heating part 53 can be controlled, for example, from room temperature to about 100° C. By using the heating part 53, evaporation of the solvent contained in the liquid material on the substrate S can be promoted, thereby supporting the drying treatment under reduced pressure.

The heating part 53 is connected to a lifting mechanism (moving part) 53a. The lifting mechanism 53a moves the heating part 53 in the Z-direction. As the lifting mechanism 53a, for example, a motor mechanism or an air-cylinder mechanism is used. By moving the heating part 53 in the Z-direction using the lifting mechanism 53a, the distance between the heating part 53 and the substrate S can be adjusted. With respect to the heating part 53, the distance to be moved and the timing to be moved by the lifting mechanism 53a can be controlled by the control part CONT.

(Second Chamber)

The second chamber CB2 is mounted on the base BB placed on the floor FL. The second chamber CB2 is formed in the shape of a rectangular box. Inside the second chamber CB2, a treatment room 60a is formed. The baking part BK is provided in the treatment room 60a. The baking part BK bakes the coating film coated on the substrate S.

The second chamber CB2 has an opening 61. The opening 61 communicates the treatment room 60a with the outside of the second chamber CB2. The opening 61 is formed on a −X-side face of the second chamber CB2. The opening 61 is formed to have a size which allows the substrate S to pass through. The substrate S is placed in or taken out of the second chamber CB2 through the opening 61.

The baking part BK has a substrate transporting part 65, a gas supply part 68, a gas exhaust part 69 and a heating chamber 70.

The substrate transporting part 65 has a plurality of rollers 67 and an arm part 71. The rollers 67 are arranged in a pair in the Y-direction on the substrate guide stage 66, and a plurality of the pairs are arranged in the X-direction. The plurality of rollers 67 supports the substrate S which is disposed in the treatment room 60a via the opening 61.

By rotating each of the rollers 67 clockwise or anti-clockwise around the Y-axis in a state where the substrate S is supported by the plurality of rollers 67, the substrate S supported by each of the rollers 67 is transported in an X-direction (+X-direction or −X-direction). A float transporting part (not shown) may be used to lift the substrate for transportation.

The arm part 71 is disposed on a platform 74, and transfers the substrate S between the plurality of rollers 67 and the heating chamber 70. The arm part 71 has a transport arm 72 and an arm actuator 73. The transport arm 72 has a substrate supporting part 72a and a moving part 72b. The substrate supporting part 72a supports the +Y-side edge and −Y-side edge of the substrate S. The moving part 72b is attached to the substrate supporting part 72a, and is movable in the X-direction and the θZ-direction.

The arm actuator 73 actuates the moving part 72b in the X-direction or the θZ-direction. When the moving part 72b is moved in the +X-direction by the arm actuator 73, the substrate supporting part 72a is inserted inside the heating chamber 70, and the substrate S is placed at a central portion of the heating chamber 70 as viewed in the Z-direction.

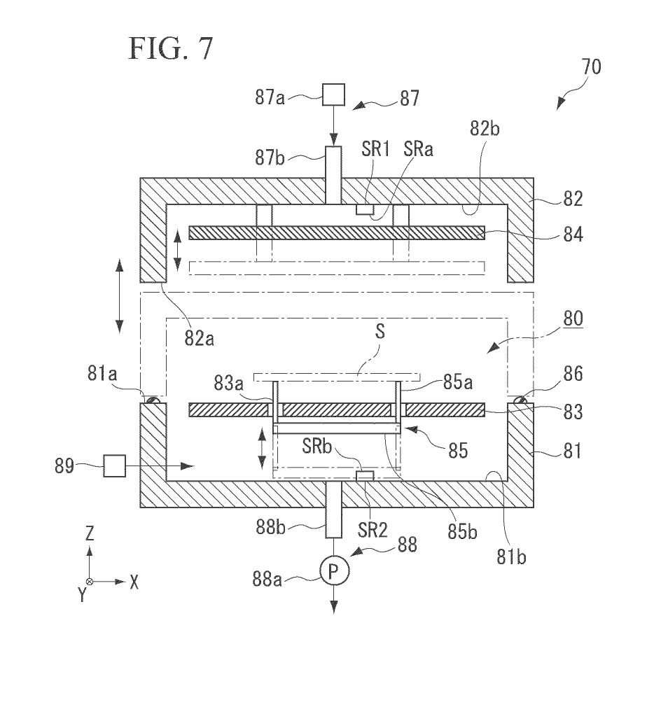

FIG. 7 is a cross-sectional view showing the configuration of the heating chamber 70.

As shown in FIG. 7, the heating chamber 70 is disposed on the platform 74, and has a first accommodation part 81, a second accommodation part 82, a first heating plate 83, a second heating plate 84, a lifting part 85, a sealing part 86, a gas supply part 87 and an exhaust part 88.

The first accommodation part 81 is formed in the shape of a rectangular open box as viewed in the Z-direction, and is mounted on the bottom of the chamber 60 such that the opening faces the +Z side. The second accommodation part 82 is formed in the shape of a rectangular open box as viewed in the Z-direction, and is disposed such that the opening faces the first accommodation part 81. The second accommodation part 82 is movable in the Z direction by using a lifting mechanism (not shown). By superimposing the edge portion 82a of the second accommodation part 82 on the edge 81a of the first accommodation part 81, the inside of the first accommodation part 81 and the second accommodation part 82 is closed. In such a case, a closed baking room 80 is formed by the first accommodation part 81, the second accommodation part 82 and the sealing part 86.

The first heating plate 83 is accommodated in the first accommodation part 81. The first heating part 83 heats a substrate S in a state where the substrate S is mounted on the first heating part 83. The first heating plate 83 is formed of, for example, quartz or the like, and is provided with a heating device such as an infrared device or a hot plate inside thereof. The temperature of the first heating plate 83 is adjustable, for example, from about 200 to 800° C. The first heating part 83 has a plurality of through-holes 83a formed thereon. The through-holes 83a allow part of the lifting part 85 to penetrate therethrough.

The second heating plate 84 is accommodated in the second accommodation part 82. The second heating plate 84 is formed of, for example, a metal material, and is provided with a heating device such as an infrared device or a hot plate inside thereof. The temperature of the second heating plate 84 is adjustable, for example, from about 200 to 800° C. The second heating plate 84 is provided to be movable independently from the second accommodation part 82 in the Z direction by a lifting mechanism (not shown). By moving the second heating plate 84 in the Z direction, the interval between the second heating plate 84 and the substrate S can be adjusted.

The lifting part 85 moves the substrate S between the arm part 71 and the first heating plate 83. The lifting part 85 has a plurality of support pins 85a and a moving part 85b which is movable in the Z direction while holding the support pins 85a. For easier discrimination of the drawings, in FIG. 7, a configuration is shown in which two support pins 85a are provided. However, in practice, it is possible to provide, for example, sixteen support pins 85a (see FIG. 7). The plurality of through-holes 83a provided on the first heating plate 83 are arranged at positions corresponding to the plurality of support pins 85a as viewed in the Z direction.

The sealing part 86 is formed on the edge portion 81a of the first accommodation part 81. As the sealing part 86, for example, an O-ring formed by a resin material or the like can be used. The sealing part 86 seals the first accommodation part 81 and the second accommodation part 82 in a state where the edge portion 82a of the second accommodation part 82 is superimposed on the first edge 81a of the first accommodation part 81. In this manner, the inside of the first accommodation part 81 and the second accommodation part 82 can be closed.

The gas supply part 87 supplies a nitrogen gas or the like to the treatment room 60a. The gas supply part 87 is connected to the +Z-side face of the chamber 60. The gas supply part 87 has a gas supply source 87a such as a gas bomb or a gas pipe, and a connection pipe 87b which connects the gas supply source 87a with the heating chamber 70. The gas supply source 87a has a supply source of a nitrogen gas and a supply source of a chalcogen element-containing gas (e.g., hydrogen sulfide, hydrogen selenide or the like). A configuration in which the gas supply source 87a has a supply source of another gas may be employed.

The exhaust part 88 suctions the treatment room 60a, and discharges the gas in the treatment room 60a outside the chamber 60. The exhaust part 88 is connected to the −Z-side face of the chamber 60. The exhaust part 88 has a suction source 88a such as a pump, and a connection pipe 88b which connects the suction source 88a with the chamber 60.

Further, in the present embodiment, inside the heating chamber 70, gas concentration detection parts SR1 and SR2 are provided. The gas concentration detection parts SR1 and SR2 detect the concentration of the predetermined gas containing a chalcogen element in the ambient atmosphere of the substrate accommodated in the heating chamber 70. Further, the gas concentration detection parts SR1 and SR2 sends the detection results to the control part CONT.

In the present embodiment, the gas concentration detection parts SR1 and SR2 are capable of detecting a gas containing at least one of sulfur and selenium as the chalcogen atom. Examples of such gas include hydrogen sulfide and hydrogen selenide. Each of the gas concentration detection parts SR1 and SR2 has at least one of a sensor capable of detecting hydrogen sulfide and a sensor capable of detecting hydrogen selenide. Further, the gas concentration detection part SR1 may have a sensor capable of detecting sublimed elemental sulfur or selenium.

The gas concentration detection part SR1 is provided on the ceiling part 82b of the second accommodation part 82 of the heating chamber 70. The detection face SRa of the gas concentration detection part SR1 faces the −Z side, and is disposed to oppose the first heating plate 83 on which the substrate S is mounted. By such a configuration, the gas concentration detection part SR1 is to oppose a face of the substrate S on which the liquid material is coated. The gas concentration detection part SR1 is preferably disposed at a position deviated from a region which directly receives the gas supplied from the connection pipe 87b of the gas supply part 87. Therefore, a configuration in which the gas concentration detection part SR1 is disposed at a position closer to the wall portion side of the second accommodation part 82 than in FIG. 7 may be employed. Further, a shielding part (not shown) which shields the gas concentration detection part SR1 from the gas may be disposed between the gas concentration detection part SR1 and the connection pipe 87b.

The position of the gas concentration detection part SR1 is not limited to the second accommodation part 82, as long as it is a position opposed to the face of the substrate, and the gas concentration detection part SR1 may be disposed at another position. As such a position, for example, a configuration may be employed in which a supporting member (not shown) is extended from a portion of the second accommodation part 82 to the −Z side of the second heating plate 84, and the gas concentration detection part SR1 is attached to the supporting member. Alternatively, a configuration in which the gas concentration detection part SR1 is disposed at a portion different from the celing part 82b of the second accommodation part 82 (e.g., a wall part) may be employed. Further, a protection part (such as a heat insulating cover, a cooling mechanism or the like) which protects wire portions connected to the gas concentration detection parts SR1 and SR2 from heat may be provided.

On the other hand, the gas concentration detection part SR2 is provided on the bottom part 81b of the first accommodation part 81 of the heating chamber 70. The gas concentration detection part SR2 is disposed in the vicinity of the exhaust part 88. More specifically, the gas concentration detection part SR2 is disposed in the vicinity of the connection pipe 88b. The detection face SRb of the gas concentration detection part SR2 faces the +Z side. The gas concentration detection part SR2 may be provided inside the connection pipe 88b.

Further, in the present embodiment, a solid supply part 89 is provided. The solid supply part 89 supplies a solid containing a chalcogen element to the inside of the heating chamber 70. Examples of the chalcogen element include a solid sulfur and a solid selenium. In FIG. 7, an example of a configuration in which the solid supply part 89 supplies a solid from the side portion of the first accommodation part 81 to the bottom part 81b is shown. However, the present invention is not limited thereto. For example, a configuration in which a solid is supplied from the ceiling part 82b side of the second accommodation part 82 to the inside of the heating chamber 70 may be employed. Alternatively, a configuration may be employed in which a solid disposing part (in the form of a base or a shelf) is formed on at least one of the first accommodation part 81 and the second accommodation part 82 in advance, and the solid supply part 89 disposes the solid on the solid disposing part. Alternatively, a configuration may be employed in which a container or an accommodation part provided with an open-and-close lid and having the solid accommodated therein is disposed inside the heating chamber 70, wherein the lid is opened when the solid is to be supplied, and the lid is closed when the solid is not to be supplied.

(Substrate Transport Path)

The second opening 12 of the substrate loading/unloading part LU, the first opening 21 and the second opening 22 of the coating part CT, the first opening 51 and the second opening 52 of the vacuum drying part VD and the opening 61 of the baking part BK are provided along a line in parallel to the X-direction. Thus, the substrate S is moved along a line in the X-direction. Further, in the path from the substrate loading/unloading part LU to the heating chamber 70 of the baking part BK, the position in the Z-direction is maintained. Thus, stirring of the gas around the substrate S can be suppressed.

(Anti-Chamber)

As shown in FIG. 1, the first chamber CB1 has anti-chambers AL1 to AL3 connected thereto.

The anti-chambers AL1 to AL3 are provided to communicate with the inside and outside of the first chamber CB1. Each of the anti-chambers AL1 to AL3 is a path through which a component of the treatment room 20a is taken out of the first chamber CB1 or the component is placed into the treatment room 20a from outside the first chamber CB1.

The anti-chamber AL1 is connected to the ejection part 31. The nozzle NZ provided in the ejection part 31 can be taken out of or placed into the treatment room 20a via the anti-chamber AL1. The anti-chamber AL2 is connected to the liquid material supply part 33. The liquid material supply part 33 can be taken out of or placed into the treatment room 20a via the anti-chamber AL2.

The anti-chamber AL3 is connected to a liquid material preparation part 36. In the liquid material preparation part 36, a liquid can be taken out of or placed into the treatment room 20a via the anti-chamber AL3. The anti-chamber AL3 is formed to have a size which allows the substrate S to pass through. Therefore, for example, when a test coating of the liquid material is to be conducted in the coating part CT, a substrate S prior to treatment can be supplied to the treatment room 20a from the anti-chamber AL3. Further, the substrate S after the test coating can be taken out from the anti-chamber AL3. Moreover, the substrate S can be taken out from the anti-chamber AL3 temporarily in emergency.

The second chamber CB2 has an anti-chamber AL4 connected thereto.

The anti-chamber AL4 is connected to the heating chamber 70. The anti-chamber AL4 is formed to have a size which allows the substrate S to pass through. Therefore, for example, when heating of the substrate S is to be conducted in the heating chamber 70, the substrate S can be supplied to the treatment room 60a from the anti-chamber AL4. Further, the substrate S after the heat treatment can be taken out from the anti-chamber AL4.

(Glove Part)

As shown in FIG. 1, the first chamber CB1 has a glove part GX1 connected thereto. Further, the second chamber CB2 has a glove part GX2 connected thereto.

The glove parts GX1 and GX2 are parts where an operator accesses the inside of the first chamber CB1 and the second chamber CB2. By inserting the hands inside the glove parts GX1 and GX2, the operator can conduct maintenance inside the first chamber CB1 and the second chamber CB2. The glove parts GX1 and GX2 are formed to have a bag-like shape. The glove parts GX1 and GX2 are respectively provided at a plurality of portions on the first chamber CB1 and the second chamber CB2. A sensor may be provided inside the first chamber CB1 and the second chamber CB2 which detects whether or not an operator has put his hand in the glove part GX1 or GX2.

(Gate Valve)

Between the second opening 12 of the substrate loading/unloading part LU and the first opening 21 of the coating part CT, a gate valve V1 is provided. The gate valve V1 is provided to be movable in the Z-direction by an actuator (not shown). By moving the gate valve V1 in the Z-direction, the second opening 12 of the substrate loading/unloading part LU and the first opening 21 of the coating part CT are simultaneously opened or closed. When the second opening 12 and the first opening 21 are simultaneously opened, a substrate S can be moved through the second opening 12 and the first opening 21.

Between the second opening 22 of the first chamber CB1 and the first opening 51 of the third chamber CB3, a gate valve V2 is provided. The gate valve V2 is provided to be movable in the Z-direction by an actuator (not shown). By moving the gate valve V2 in the Z-direction, the second opening 22 of the first chamber CB1 and the first opening 51 of the third chamber CB3 are simultaneously opened or closed. When the second opening 22 and the first opening 51 are simultaneously opened, a substrate S can be moved through the second opening 22 and the first opening 51.

Between the second opening 52 of the third chamber CB3 and the opening 61 of the second chamber CB2, a gate valve V3 is provided. The gate valve V3 is provided to be movable in the Z-direction by an actuator (not shown). By moving the gate valve V3 in the Z-direction, the second opening 52 of the third chamber CB3 and the opening 61 of the second chamber CB2 are simultaneously opened or closed. When the second opening 52 and the opening 61 are simultaneously opened, a substrate S can be moved through the second opening 52 and the opening 61.

(Control Device)

The control part CONT is a part which has the overall control of the coating apparatus CTR. Specifically, the control part CONT controls the operations of the substrate loading/unloading part LU, the coating part CT, the vacuum drying part VD, the baking part BK and the gate valves V1 to V3. As an example of the adjusting operation, the control part CONT controls the amount of gas to be supplied from the gas supply part 37a, based on the detection results of the solvent concentration sensors SR1 to SR4. The control part CONT has a timer or the like (not shown) for measuring the treatment time.

(Coating Method)

Next, a coating method according to one embodiment of the present invention will be described. In this embodiment, a coating film containing a metal is formed on the substrate S by using the coating apparatus CTR having the above-described configuration. The operations performed by the respective parts of the coating apparatus CTR are controlled by the control part CONT.

Firstly, the control part CONT loads a substrate S on the substrate loading/unloading part LU from the outside. In this case, the control part CONT closes the gate valve V1, opens the lid portion 14 and accommodates the substrate S in the accommodation room 10a of the chamber 10. After the substrate S is accommodated in the accommodation room 10a, the control part CONT closes the lid portion 14.

After the lid portion 14 is closed, the control part CONT opens the gate valve V1, so as to communicate the accommodation room 10a of the chamber 10 with the treatment room 20a of the first chamber CB1 of the coating part CT. After opening the gate valve V1, the control part CONT transports the substrate S in the X-direction using the substrate transporting part 15.

After a portion of the substrate S has been inserted into the treatment room 20a of the first chamber CB1, the control part CONT uses the substrate transporting part 25 to completely load the substrate S into the treatment room 20a. After the substrate S has been loaded, the control part CONT closes the gate valve V1. After closing the gate valve V1, the control part CONT transports the substrate S to the treatment stage 28.

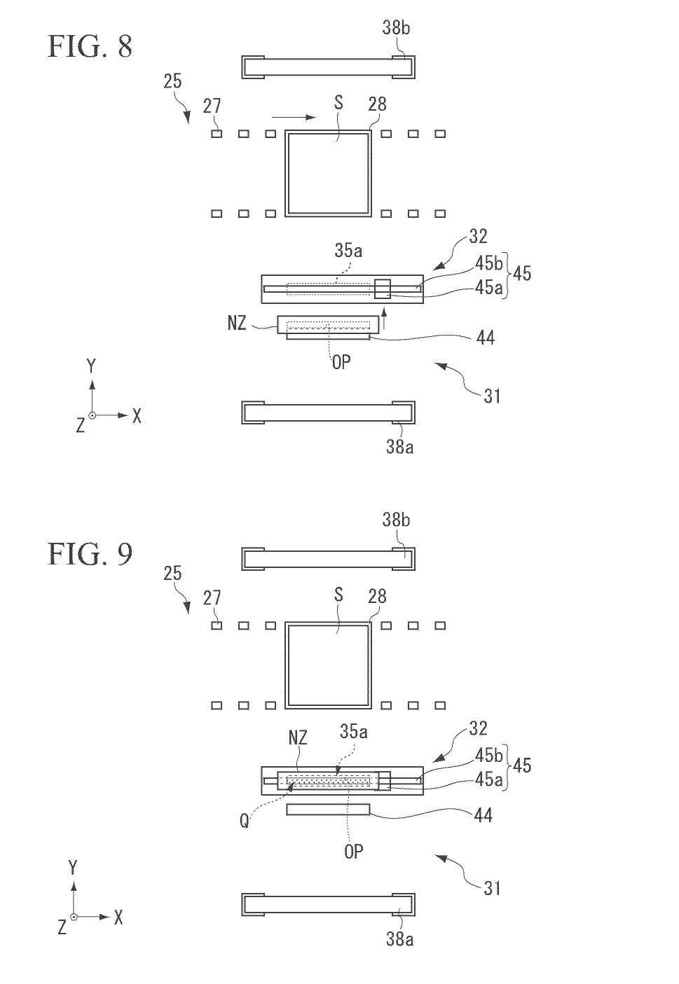

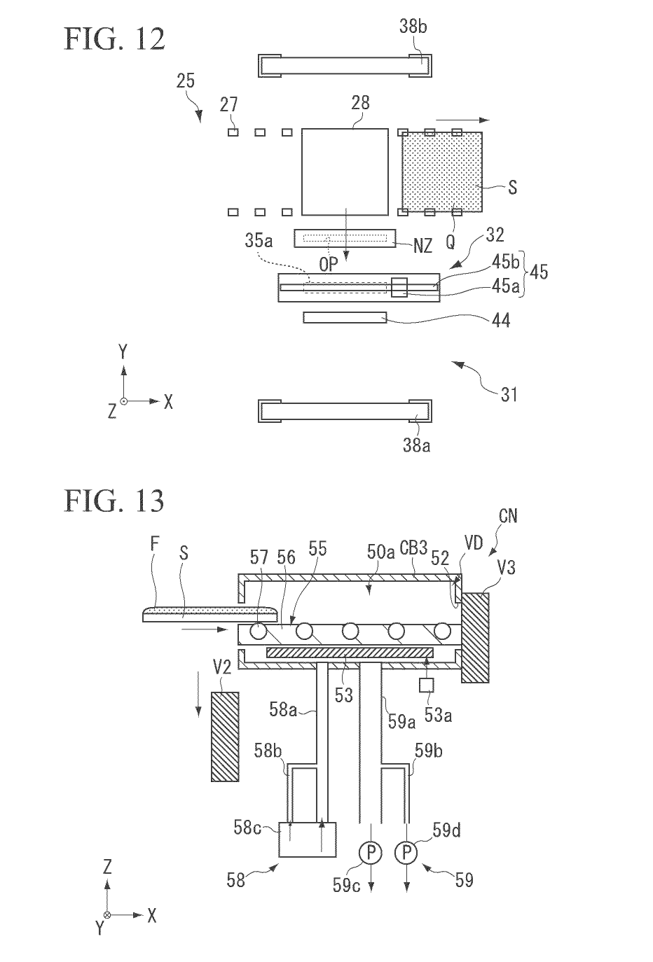

FIG. 8 is a diagram showing a simplified configuration of the coating part CT in which part of the components have been abbreviated. Herebelow, the same applies to FIG. 9 to FIG. 12. As shown in FIG. 8, when the substrate S is mounted on the treatment stage 28, a coating treatment is conducted by the coating part CT. Prior to the coating treatment, the control part CONT closes the gate valves V1 and V2, and conducts supplying and suctioning of an inert gas using the gas supplying part 37a and the gas exhaust part 37b.

By this operation, the atmosphere and the pressure of the treatment room 20a can be adjusted. After adjusting the atmosphere and the pressure of the treatment room 20a, the control part CONT uses the nozzle actuator NA (not shown in FIG. 8) to move the nozzle NZ from the nozzle standby part 44 to the nozzle-tip control part 45. Thereafter, during the coating treatment, the control part CONT continuously conducts the adjusting operation of the atmosphere and the pressure of the treatment room 20a.

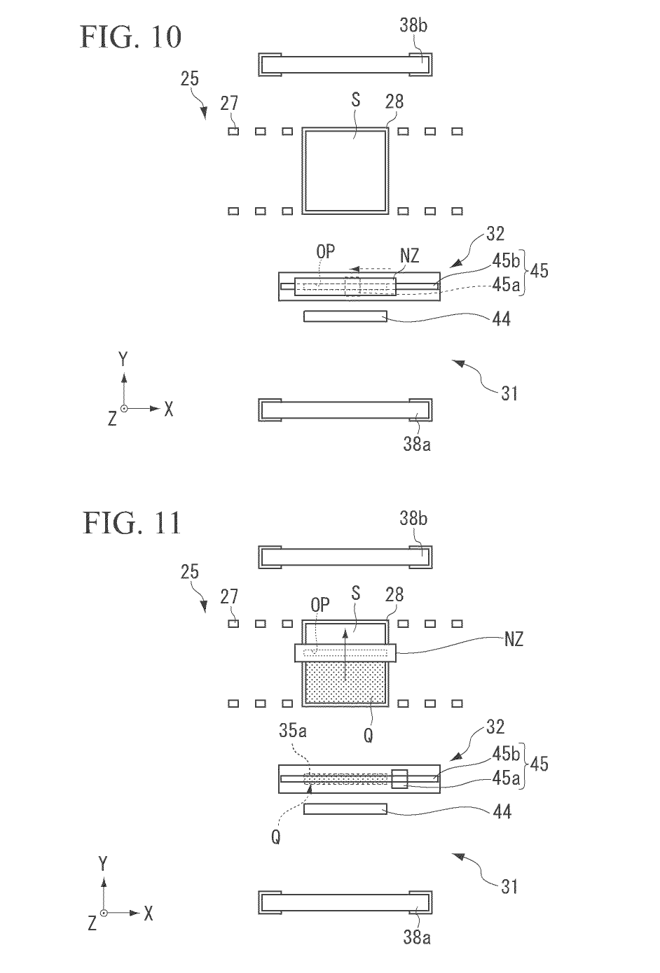

When the nozzle NZ reaches the nozzle-tip control part 45, as shown in FIG. 9, the control part CONT conducts a preliminary ejection operation of the nozzle NZ. In the preliminary ejection operation, the control part CONT ejects the liquid material Q from the ejection opening OP. After the preliminary ejection operation, as shown in FIG. 10, the control part CONT moves the wiping part 45a along the guide rail 45b in the X-direction, so as to wipe the tip TP of the nozzle NZ and the inclined part in the vicinity thereof.

After wiping the tip TP of the nozzle NZ, the control part CONT moves the nozzle NZ to the treatment stage 28. After the ejection opening OP of the nozzle NZ reaches the −Y-side end of the substrate S, as shown in FIG. 11, the control part CONT ejects the liquid material Q from the ejection opening OP to the substrate S while moving the nozzle NZ in the +Y-direction at a predetermined speed. By this operation, a coating film F of the liquid material Q is formed on the substrate S.

After forming a coating film of the liquid material Q on a predetermined region of the substrate S, the control part CONT uses the substrate transporting part 25 to move the substrate S from the treatment stage 28 to the second stage 26B in the +X-direction. Further, the control part CONT moves the nozzle NZ in the −Y-direction, and returns the nozzle NZ to the nozzle standby part 44.

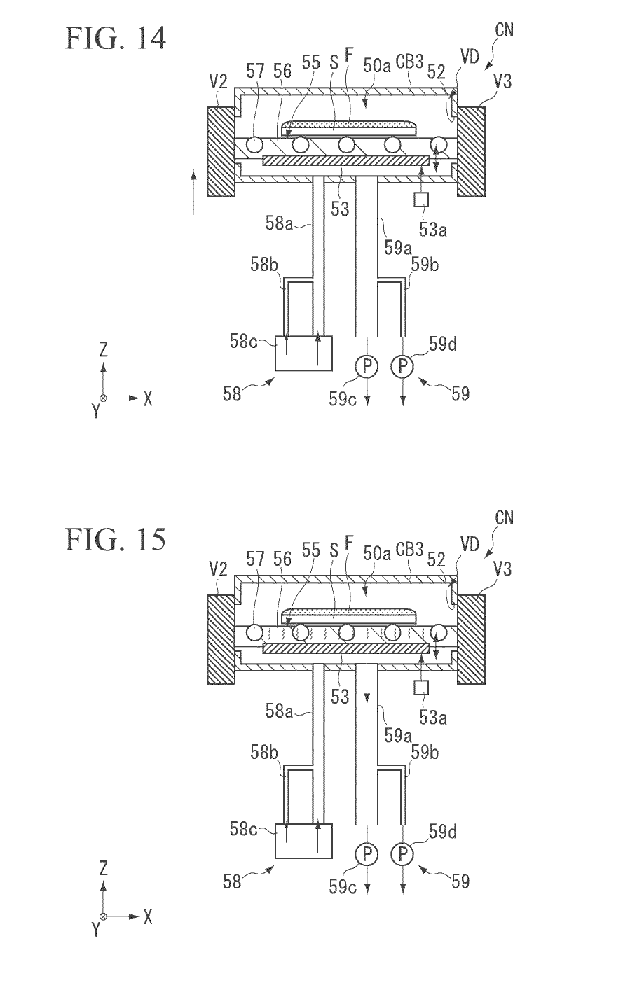

When the substrate S reaches the second opening 22 of the first chamber CB1, as shown in FIG. 13, the control part CONT opens the gate valve V2, and transports the substrate S from the first chamber CB1 to the second chamber CB2. In the transporting step, the substrate S passes through the third chamber CB3 disposed at the connection part CN. When the substrate S passes through the third chamber CB3, the control part CONT conducts a drying treatment of the substrate S using the vacuum drying part VD. Specifically, after the substrate S is accommodated in the treatment room 50a of the third chamber CB3, as shown in FIG. 14, the control part CONT closes the gate valve V2.

After closing the gate valve V2, the control part CONT uses the lifting mechanism 53a to adjust the position of the heating part 53 in the Z-direction. Thereafter, as shown in FIG. 15, the control part CONT uses the gas supply part 58 to adjust the atmosphere inside the treatment room 50a and uses the gas exhaust part 59 to reduce the pressure inside the treatment room 50a. When the pressure inside the treatment room 50a is reduced by this operation, evaporation of the solvent contained in the coating film of the liquid material Q formed on the substrate S is promoted, and the coating film is dried. The control part CONT may adjust the position of the heating part 53 in the Z-direction using the lifting mechanism 53a while reducing the pressure inside the treatment room 50a using the gas exhaust part 59.

Further, as shown in FIG. 15, the control part CONT uses the heating part 53 to heat the coating film F on the substrate S. By this operation, evaporation of the solvent contained in the coating film F on the substrate S is promoted, so that the vacuum drying treatment can be conducted in a short time. The control part CONT may adjust the position of the heating part 53 in the Z-direction using the lifting mechanism 53a while conducting the heating operation by the heating part 53.

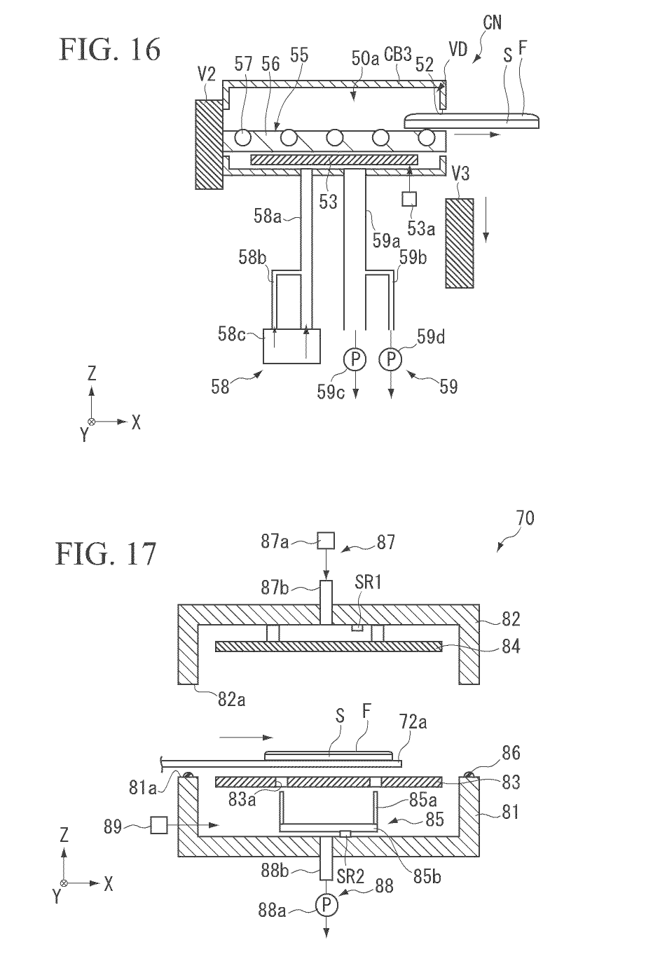

After the vacuum drying treatment, as shown in FIG. 16, the control part CONT opens the gate valve V3, and transports the substrate S from the connection part CN to the second chamber CB2. After the substrate S is accommodated in the treatment room 60a of the second chamber CB2, the control part CONT closes the gate valve V3.

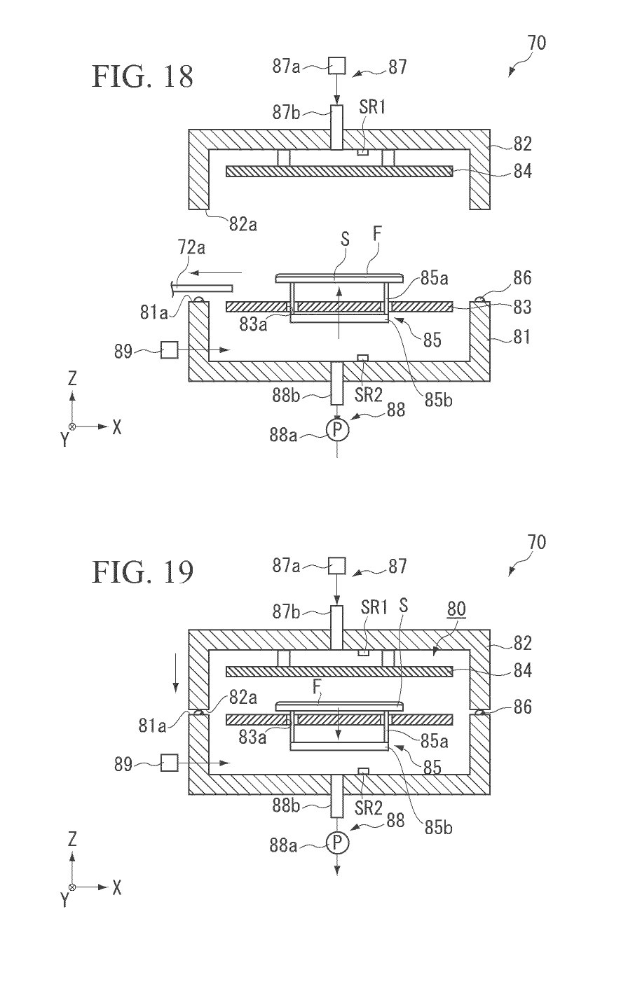

As shown in FIG. 17, by the movement of the substrate supporting part 72a, the substrate S is disposed above a central portion of the first heating plate 83. Thereafter, as shown in FIG. 18, the control part CONT moves the lifting part 85 in the +Z direction. By this operation, the substrate S leaves the substrate supporting part 72a of the transport arm 72, and is supported by the plurality of support pins 85a of the lifting part 85. In this manner, the substrate S is delivered from the substrate supporting part 72a to the lifting part 85. After the substrate S has been supported by the support pins 85a of the lifting part 85, the control part CONT withdraws the substrate supporting part 72a outside the heating chamber 70 in the −X direction.

After withdrawing the substrate supporting part 72a, as shown in FIG. 19, the control part CONT moves the lifting part 85 in the −Z direction, and also moves the second accommodation part 82 in the −Z direction. By this operation, the edge portion 82a of the second accommodation part 82 is superimposed on the edge 81a of the first accommodation part 81, so that the sealing part 86 is sandwiched between the edge portion 82a and the edge portion 81a. As a result, a closed baking room 80 is formed by the first accommodation part 81, the second accommodation part 82 and the sealing part 86 (accommodation step).

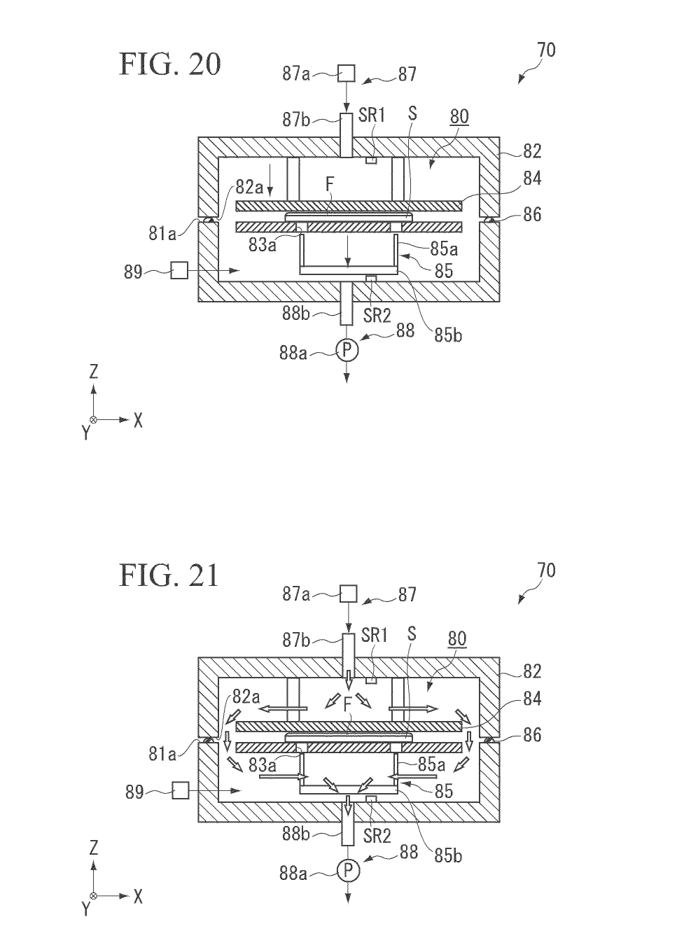

After forming the baking room 80, as shown in FIG. 20, the control part CONT moves the lifting part 85 in the −Z direction and mounts the substrate S on the first heating plate 83. After the substrate S has been mounted on the first heating plate 83, the control part CONT moves the second heating plate 84 in the −Z direction, so that the second heating plate 84 approaches the substrate S. The control part CONT appropriately adjusts the position of the second heating plate 84 in the Z direction.

After adjusting the position of the second heating plate 84 in the Z direction, as shown in FIG. 21, the control part CONT supplies a nitrogen gas, a hydrogen sulfide gas and/or a hydrogen selenide gas to the baking room 80 by using the gas supply part 87, and suctions the baking room 80 by using the exhaust part 88. By this operation, not only the atmosphere and pressure inside the baking room 80 are adjusted, but also a stream of the nitrogen gas, the hydrogen sulfide gas and/or the hydrogen selenide gas is formed from the second accommodation part 82 to the first accommodation part 81. In a state where the stream of the nitrogen gas, the hydrogen sulfide gas and/or the hydrogen selenide gas is formed, the control part CONT actuates the first heating plate 83 and the second heating plate 84, so as to perform the baking operation of the substrate S (heating step). By this operation, the solvent component is evaporated from the coating film F on the substrate S, and bubbles contained in the coating film F are removed. Further, by the stream of the nitrogen gas, the hydrogen sulfide gas and/or the hydrogen selenide gas, the solvent component evaporated from the coating films F and the bubbles are swept away, and suctioned by the exhaust part 88.

In the baking operation of the substrate S, the control part CONT detects the concentration of a predetermined gas containing a sulfur atom and/or selenium atom (e.g., a hydrogen sulfide gas or a hydrogen selenide gas) within the gas inside the heating chamber 70 (detection step). The control part CONT uses the gas concentration detection parts SR1 and SR2 for the detection. After a hydrogen sulfide gas and/or a hydrogen selenide gas is supplied to the baking room 80 from the gas supply part 87, the control part CONT operates the gas concentration detection parts SR1 and SR2 to detect the concentration of the hydrogen sulfide gas and/or the hydrogen selenide gas. The gas concentration detection parts SR1 and SR2 detect the concentration of the hydrogen sulfide gas and/or the hydrogen selenide gas, and the detection results are sent to the control part CONT.

By the gas concentration detection part SR1, detection is conducted at a position opposite to a face of the substrate S on which the liquid material is coated. Therefore, the concentration of the hydrogen sulfide gas and/or the hydrogen selenide gas can be efficiently detected. Further, by the gas concentration detection part SR2, the concentration of the hydrogen sulfide gas and/or the hydrogen selenide gas contained in the gas discharged from the connection pipe 88b is detected.

Based on the detection results, the control part CONT controls the concentration of the hydrogen sulfide gas and/or the hydrogen selenide gas inside the heating chamber 70 (inside the baking room 80) (controlling step). In the controlling, when the detection results exceed a predetermined first threshold value of a lower limit the control part CONT and are lower than a predetermined second threshold value of an upper limit, the control part CONT continues to supply the hydrogen sulfide gas and/or the hydrogen selenide gas in the manner as described above, and conducts a heating operation.

On the other hand, when the detection results are lower than the first threshold value (lower limit threshold value), the control part CONT uses the gas supply part 87 to supply a hydrogen sulfide gas and/or a hydrogen selenide gas into the heating chamber 70 (supplying step). The supplying step includes increasing the amount of the hydrogen sulfide gas and/or the hydrogen selenide gas supplied to the heating chamber 70. The control part CONT continues to increase the amount of the hydrogen sulfide gas and/or the hydrogen selenide gas supplied until the detection result exceeds the first threshold value.

Further, when the detection result exceeds the second threshold value (upper limit threshold value), at least one of an operation in which the amount of the hydrogen sulfide gas and/or the hydrogen selenide gas supplied by the gas supply part 87 is decreased, an operation in which the hydrogen sulfide gas and/or the hydrogen selenide gas is stopped from being supplied and an operation in which the gas inside the heating chamber 70 is discharged by the exhaust part 88 is conducted, so as to decrease the concentration of the hydrogen sulfide gas and/or the hydrogen selenide gas inside the heating chamber 70. The control part CONT conducts at least one of decreasing the amount of the hydrogen sulfide gas and/or the hydrogen selenide gas supplied, stopping the supplying and discharging (discharge step) until the detection result becomes lower than the second threshold value.

In addition, in the baking operation, at least one of the metal components contained in the coating films F is heated to its melting point or higher, so as to dissolve at least a portion of the coating film F. For example, in the case where the coating film F is used for a CZTS solar cell, among the components that constitute the coating film F, S and Se are heated to their melting points or higher, so as to liquefy these substances and aggregate the coating film F. Thereafter, the coating film F is cooled to a temperature at which the coating film F is solidified. By solidifying the coating films F, the strength of the coating films F can be enhanced.

After the baking operation has been completed, the control part CONT transports the substrate S in the −X direction. Specifically, the substrate S is unloaded from the baking part BK via the heating chamber 70, the arm part 71 and the substrate guide stage 66, and is returned to the substrate loading/unloading part LU via the coating part CT. After the substrate S has been returned to the substrate loading/unloading part LU, the control part CONT opens the lid portion 14 in a state where the gate valve V1 is closed. Thereafter, an operator collects the substrate S in the chamber 10, and accommodates a new substrate S in the accommodation room 10a of the chamber 10.

In the case where, after the substrate S has been returned to the substrate loading/unloading part LU, another coating film is formed to be superimposed on the coating film F formed on the substrate S, the control part CONT transports the substrate S to the coating part CT again, and repeats the coating treatment, the vacuum drying treatment and the baking treatment. In this manner, coating film F is laminated on the substrate S.

As explained above, according to the present embodiment, since gas concentration detection parts SR1 and SR2 are provided which are capable of detecting the concentration of a gas containing a chalcogen element (e.g., hydrogen sulfide, hydrogen selenide) within the gas inside the heating chamber 70, the change in the concentration of hydrogen sulfide and/or hydrogen selenide in the ambience of the substrate S can be detected. As a result, it becomes possible to detect the change in the ambient environment of the substrate S at the time of heating.

Further, since the gas supply part 87 and the exhaust part 88 are provided as the control part which uses the detection results of the gas concentration detection parts SR1 and SR2 to control the concentration of hydrogen sulfide and/or hydrogen selenide within the atmosphere inside the heating chamber 70, it becomes possible to use the detection results of the gas concentration detection parts SR1 and SR2 to control the concentration of hydrogen sulfide and/or hydrogen selenide within the atmosphere inside the heating chamber 70. As a result, it becomes possible to control the ambient environment of the substrate S.

The technical scope of the present invention is not limited to the above-described embodiment, but may be appropriately modified into various forms without departing from the spirit of the present invention.

For example, in the aforementioned embodiment, explanation was given taking example of the case where the control part CONT increases the amount of the hydrogen sulfide gas and/or the hydrogen selenide gas inside the heating chamber 70 when the detection result is lower than the first threshold value, so as to control the concentration of the hydrogen sulfide gas and/or the hydrogen selenide gas inside the heating chamber 70 (baking room 80). However, the present invention is not limited thereto.

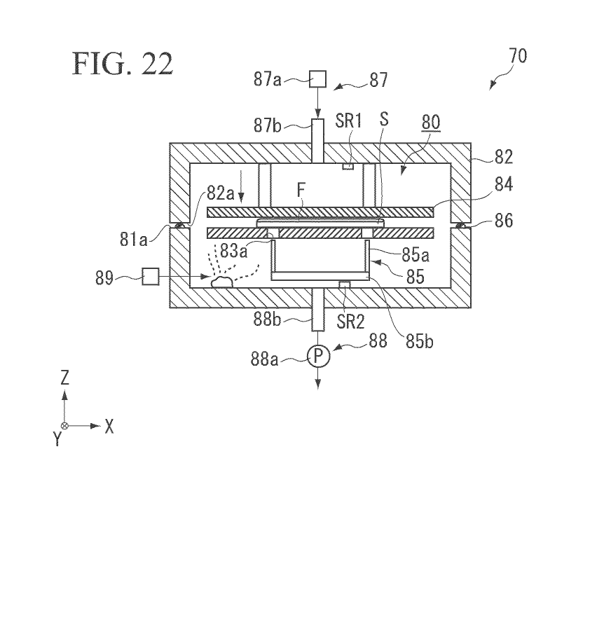

FIG. 22 is a diagram showing a step in the baking treatment. As shown in FIG. 22, the control part CONT may use the solid supply part 89 to supply a solid containing an elemental sulfur or selenium to the inside of the heating chamber 70 (supplying step). In such a case, sulfur and/or selenium contained in the solid supplied to the inside of the heating chamber 70 is sublimed by the heat inside the heating chamber 70, and contributes to increasing the sulfur atom concentration and the selenium atom concentration in the atmosphere.

Further, for example, in the aforementioned embodiment, explanation was given taking example of a configuration in which the gas concentration detection parts SR1 and SR2 are disposed inside the heating chamber 70. However, the present invention is not limited thereto. For example, a configuration may be employed in which the gas at a predetermined position inside the heating chamber 70 is discharged, and the concentration of hydrogen sulfide and/or hydrogen selenide contained in the discharged gas is detected.

Further, for example, in the aforementioned embodiment, explanation was given taking example of a configuration in which the gas concentration detection parts SR1 and SR2 are provided inside the heating chamber 70 disposed in the baking part BK. However, the present invention is not limited thereto. For example, a configuration may be employed in which gas concentration detection parts having the same configuration as that of the gas concentration detection part SR1 and SR2 are disposed on the third chamber CB3 that connects the first chamber CB1 and the second chamber CB2. In such a case, during the heating by the vacuum drying part VD, the concentration of the hydrogen sulfide gas and/or the hydrogen selenide gas in the atmosphere can be detected, and the concentration can be adjusted.

Further, a configuration in which gas concentration detection parts having the same configuration as that of the gas concentration detection part SR1 and SR2 are disposed on the first chamber CB1 may be employed. In the coating treatment by the coating part CT, there are cases where a gas containing a chalcogen element (e.g., a hydrogen sulfide gas, a hydrogen selenide gas and the like) is generated. Therefore, it is desirable to detect the change in the ambient environment of the substrate at the time of the coating treatment.

In such a case, when the substrate S is accommodated in the first chamber CB1 (first accommodation step), and a coating treatment is conducted to the substrate S by the coating part CT (first treating step), it becomes possible to conduct the concentration of hydrogen sulfide gas and/or the hydrogen selenide gas in the atmosphere at the time of the coating treatment.

The position of the gas concentration detection part may be, for example, a position along the moving path of the nozzle NZ. Alternatively, for example, a discharge port (not shown) may be provided, and the gas concentration detection part may be disposed at the discharge port or a position in the vicinity of the discharge port. Alternatively, for example, the gas concentration detection part may be disposed at a position between the liquid material supply part 33 and the waste liquid storing part 35, or a position on the +X side or the −X side of the nozzle standby part 44. Alternatively, the gas concentration detection part may be disposed outside the first chamber CB1 (e.g., outer wall).

A configuration may be employed in which the gas concentration detection part is provided inside at least one chamber selected from the first chamber CB1, the second chamber CB2 (heating chamber 70) and the third chamber CB3. In such a case, detection of the concentration of the hydrogen sulfide gas and/or the hydrogen selenide gas within the atmosphere can be conducted during at least one of the coating treatment, the vacuum drying treatment and the heating treatment (detection step), and the concentration can be controlled.

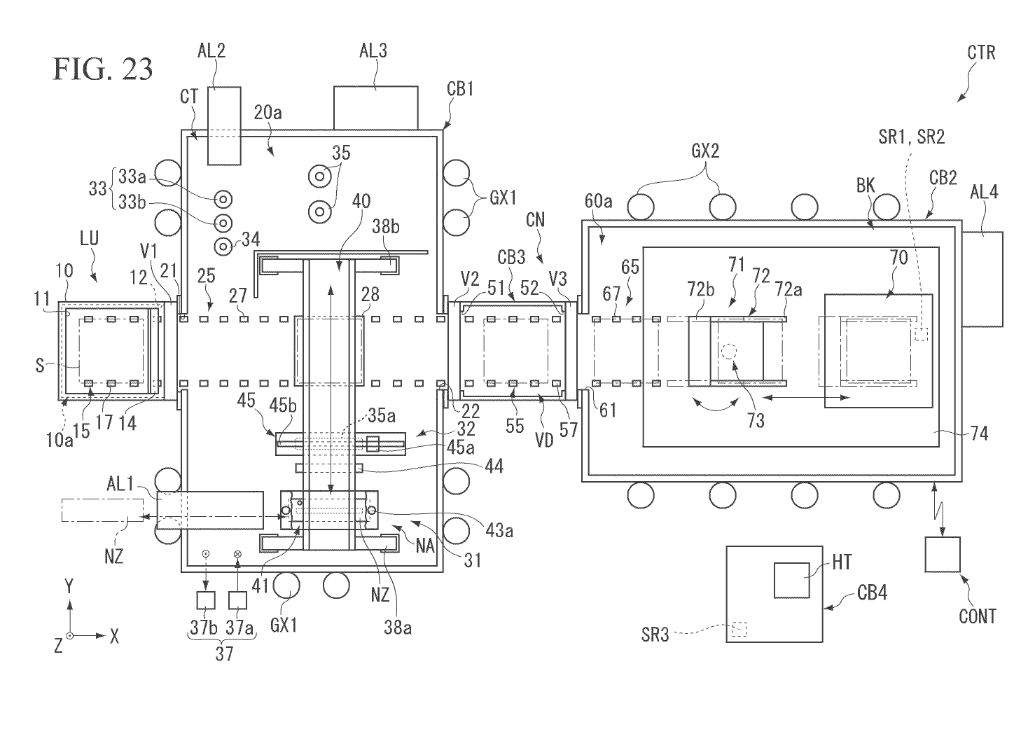

In the aforementioned embodiment, explanation was given taking example of a configuration in which the baking operation is conducted by the baking part in the second chamber CB2. However, the present invention is not limited thereto. For example, as shown in FIG. 23, a configuration may be employed in which a fourth chamber CB4 is provided at a position different from the second chamber CB2, and the substrate S is heated by a heating part HT provided on the fourth chamber CB4.

In this case, for example, a coating film F is laminated on the substrate S, and then, a heat treatment (second heating step) can be conducted for baking the laminated coating film F by the heating part HT of the fourth chamber CB4. In the second heating step, the heat treatment for heating the coating film F is conducted at a heating temperature higher than that in the heat treatment by the baking part BK. By this heating treatment, the solid contents (metal components) of the laminated coating film F can be crystallized, thereby further enhancing the film quality of the coating film F.

The heating after laminating the coating film F on the substrate S may be performed by the baking part BK of the second chamber CB2. In such a case, in the baking part BK, the heating temperature for baking the laminated coating film F can be controlled to become higher than the heating temperature for baking each layer of the coating film F.

A configuration may be employed in which a gas concentration detection part SR3 having the same configuration as that of the gas concentration detection parts SR1 and SR2 in the aforementioned embodiment is provided inside the fourth chamber CB4. In such a case, the concentration of the hydrogen sulfide gas and/or the hydrogen selenide gas can be detected by the gas concentration detection part SR3 during the heating in the fourth chamber CB4. Further, based on the detection result of the gas concentration detection part SR3, the atmosphere inside the fourth chamber can be controlled.

In the aforementioned embodiment, explanation was given taking example of a configuration in which a lifting mechanism 53a moves the heating part 53 to adjust the distance between the substrate S and the heating part 53 within the third chamber CB3. However, the present invention is not limited thereto. For example, a configuration may be employed in which the lifting mechanism 53a is capable of moving not only the heating part 53, but also the substrate S in the Z direction. Alternatively, a configuration in which the lifting mechanism 53a is capable of moving only the substrate S in the Z direction may be employed.

In the aforementioned embodiment, explanation was given taking example of a configuration in which the heating part 53 is provided on the −Z side (lower side in the vertical direction) of the substrate S in the vacuum drying part VD. However, the present invention is not limited thereto. For example, a configuration in which the heating part 53 is provided on the +Z side of the substrate S may be employed. Alternatively, a configuration may be employed in which the heating part 53 is movable between a position on the −Z side of the substrate S and a position on the +Z side of the substrate S. In this case, the heating part 53 has a shape which enables the heating part 53 to pass through the plurality of rollers 57 constituting the substrate transporting part 55 (e.g., the heating part 53 is provided with openings).

Furthermore, with respect to the configuration of the coating apparatus CTR, as shown in FIG. 25 for example, a first chamber CB1 having a coating part CT, a connection part CN having a vacuum drying part VD and a second chamber CB2 having a baking part BK may be repeatedly arranged on the +X-side of the substrate loading/unloading part LU.

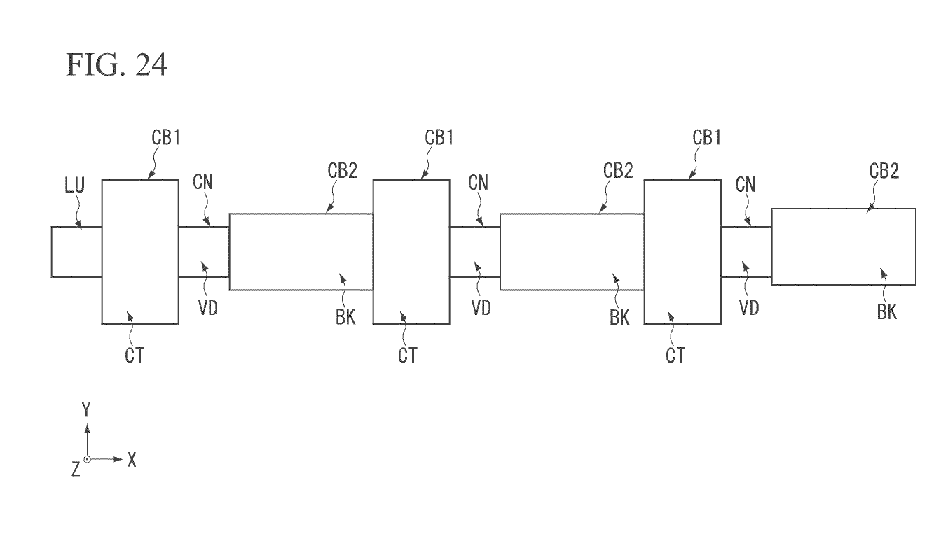

In FIG. 24, a configuration in which the first chamber CB1, the connection part CN and the second chamber CB2 are repeatedly arranged three times is shown. However, the present invention is not limited to this configuration, and a configuration in which the first chamber CB1, the connection part CN and the second chamber CB2 are repeatedly arranged twice, or a configuration in which the first chamber CB1, the connection part CN and the second chamber CB2 are repeatedly arranged four times may be employed.

According to this configuration, since the first chamber CB1, the connection part CN and the second chamber CB2 are repeatedly arranged in series in the X-direction, the substrate S can be transported in one direction (+X-direction), and there is no need to transport the substrate S back and forth. Therefore, the step of laminating the coating film on the substrate S can be continuously performed. As a result, coating films can be efficiently formed on the substrate S.

The form and combinations of the components shown in the aforementioned embodiment is only one example, and can be modified depending on the design requirements. For example, in the aforementioned embodiment, the coating part CT has a configuration which uses a slit-type nozzle NZ, but the present invention is not limited thereto. For example, a center-dripping-type coating part or an ink jet coating part may be used. Alternatively, for example, the liquid material disposed on the substrate S may be diffused by using a squeezer or the like so as to be coated thereon.

Further, for example, in the case where treatment is conducted using the above coating apparatus CTR, if desired, in at least one of the first chamber CB1, the second chamber CB2, the third chamber CB3 and the chamber apparatus including the heating chamber 70, a maintenance treatment or a treatment (e.g., transfer of the structure, cleaning, controlling the atmosphere, controlling the temperature, or the like) for rendering the ambient conditions or internal conditions to a predetermined state (e.g., initial conditions, predetermined atmosphere, predetermined temperature, or the like) can be appropriately conducted at a predetermined timing during operation (e.g., before or after various treatments in each chamber, such as before loading the substrate S to the chamber apparatus, after unloading the substrate S from the chamber apparatus, before ejecting the liquid material Q from the nozzle NZ, after ejecting the liquid material Q, before and after heating by the heating part 53, before and after heating by the first heating plate 83 and the second heating plate 84, and the like) or in a non-operating state.

Further, in the case where the above maintenance treatment or the above treatments for adjusting to a predetermined state are conducted, for example, washing can be conducted with a washing liquid. Further, by using the gas supply part 58, the gas supply part 87 or a corresponding component, at least one or a plurality of gases selected from a nitrogen gas, an oxygen gas, an argon gas, air and water vapor may be appropriately supplied around or inside each chamber apparatus. Further, the transporting system (e.g., rollers, arms, and the like) may be configured to be operable is necessary.

Further, in the aforementioned embodiment, when a configuration in which the coating apparatus CTR is accommodated in one room is employed, a gas supply/exhaust part which adjusts the atmosphere inside the room may be provided. In such a case, hydrazine present in the atmosphere inside the room may be discharged using the gas supply/exhaust part, so that the atmosphere of the entire room can be cleaned, thereby more reliably suppressing change in the coating conditions.

Each of the components described in the above embodiment and the modified examples can be appropriately combined without departing from the scope of the present invention. Further, part of the components among the plurality of components combined may be appropriately not used.

What is claimed is:

1. A substrate treating apparatus comprising:
a chamber capable of accommodating a substrate;
a treating part which conducts a predetermined treatment associated with forming a coating film containing a metal to the substrate accommodated in the chamber; and
a detection part which detects a concentration of a predetermined gas containing a chalcogen element within a gas inside the chamber.

2. The substrate treating apparatus according to claim 1, wherein the predetermined treatment comprises at least one treatment selected from the group consisting of a coating treatment in which a liquid material containing the metal and a solvent is applied to the substrate, and a heating treatment in which the substrate having the liquid material coated thereon is heated.

3. The substrate treating apparatus according to claim 1, further comprising a control part which controls the concentration of the predetermined gas inside the chamber, using a detection result of the detection part.

4. The substrate treating apparatus according to claim 3, wherein the control part comprises a supply part which supplies at least one of the predetermined gas and a solid containing the chalcogen element into the chamber.

5. The substrate treating apparatus according to claim 3, wherein the control part comprises an exhaust part which discharges the predetermined gas inside the chamber.

6. The substrate treating apparatus according to claim 5, wherein the detection part is preferably disposed near the exhaust part.

7. The substrate treating apparatus according to claim 1, wherein the detection part is disposed to oppose a face of the substrate on which the liquid material is coated.

8. The substrate treating apparatus according to claim 1, wherein the detection part is provided at a plurality of portions inside the chamber.

9. The substrate treating apparatus according to claim 1, wherein the predetermined gas comprises at least one of hydrogen sulfide and hydrogen selenide.

10. A substrate treating apparatus including:
a first chamber capable of accommodating a substrate;
a first treating part which conducts a first treatment associated with forming a coating film containing a metal to the substrate accommodated in the first chamber;
a second chamber capable of accommodating the substrate to which the first treatment has been conducted;
a second treating part which conducts a second treatment associated with forming a coating film containing a metal to the substrate accommodated in the second chamber; and
a detection part which detects a concentration of a predetermined gas containing a chalcogen element within a gas inside at least one of the first chamber and the second chamber.

11. The substrate treating apparatus according to claim 10, wherein
the first treatment comprises a coating treatment in which a liquid material containing the metal and a solvent is applied to the substrate, and
the second treatment comprises a heating treatment in which the substrate having the liquid material coated thereon is heated.

12. A substrate treating method comprising:
an accommodation step in which a substrate is accommodated in a chamber;
a treating step in which a predetermined treatment associated with forming a coating film containing a metal is conducted to the substrate accommodated in the chamber; and
a detection step in which a concentration of a predetermined gas containing a chalcogen element within a gas inside the chamber is detected during the treating step.

13. The substrate treating method according to claim 12, wherein the predetermined treatment comprises at least one treatment selected from the group consisting of a coating treatment in which a liquid material containing the metal and a solvent is applied to the substrate, and a heating treatment in which the substrate having the liquid material coated thereon is heated.

14. The substrate treating method according to claim 12, which further comprises a controlling step in which the concentration of the predetermined gas inside the chamber is controlled using a detection result of the detection step.

15. The substrate treating method according to claim 14, wherein the controlling step comprises a supplying step in which at least one of the predetermined gas and a solid containing the chalcogen element is supplied into the chamber.

16. The substrate treating method according to claim 12, wherein the controlling step comprises a discharge step in which the predetermined gas inside the chamber is discharged from an exhaust part.

17. The substrate treating method according to claim 16, wherein the detection step comprises detecting the concentration of the predetermined gas near the exhaust part.

18. The substrate treating method according to claim 12, wherein the detection step comprises detecting the concentration of the predetermined gas at a position opposite to a face of the substrate on which the liquid material is coated.

19. The substrate treating method according to claim 12, wherein the detection step comprises detecting the concentration of the predetermined gas at a plurality of portions inside the chamber.

20. The substrate treating method according to claim 12, wherein the predetermined gas comprises at least one of hydrogen sulfide and hydrogen selenide.

21. A substrate treating method comprising:
a first accommodation step in which a substrate is accommodated in a first chamber;
a first treating step in which a first treatment associated with forming a coating film containing a metal is conducted to the substrate accommodated in the first chamber;
a second accommodation step in which the substrate to which the first treatment has been conducted is accommodated in a second chamber;
a second treating step in which a second treatment associated with forming a coating film containing a metal is conducted to the substrate accommodated in the second chamber; and
a detection step in which a concentration of a predetermined gas containing a chalcogen element within a gas inside a chamber where the substrate has been accommodated in at least one of the first treating step and the second treating step is detected.

22. The substrate treating method according to claim 21, wherein
the first treatment comprises a coating treatment in which a liquid material containing the metal and a solvent is applied to the substrate, and
the second treatment comprises a heating treatment in which the substrate having the liquid material coated thereon is heated.
